(19) United States
(12) Patent Application Publication
(10) Pub. No.: US 2006/0066431 A1
(43) Pub. Date: Mar. 30, 2006

(54) Adjustable differential inductor

(76) Inventors: Seema B. Anand, Rancho Palos Verdes, CA (US); Lijun Zhang, Irvine, CA (US)

Correspondence Address: GARLICK HARRISON & MARKISON LLP, P.O. BOX 160727, AUSTIN, TX, 78716-0727, US

(21) Appl. No.: 10/958,607

(22) Filed: Oct. 5, 2004

Related U.S. Application Data
(60) Provisional application No. 60/609,732, filed on Sep. 14, 2004.

(51) Int. Cl. H01F 21/00; H04B 1/16; H01Q 11/12; H01L 29/00

(52) U.S. Cl. 336/137; 455/341; 455/127.3; 257/529; 257/531

(57) ABSTRACT

An adjustable differential inductor includes a first winding section, a second winding section, a third winding section, a fourth winding section, and a switching network operably coupled to configure the first, second, third, and fourth windings for a first differential inductance in a first mode and to configure two of the first, second, third, and fourth windings for a second differential inductance in a second mode.

### CROSS REFERENCE TO RELATED PATENTS

This invention is claiming priority under 35 USC § 119(e) to a provisionally filed patent application having the same title as the present patent application, a filing date of Sep. 14, 2004, and an application number of 60/609,732.

### BACKGROUND OF THE INVENTION

1. Technical Field of the Invention

This invention relates generally to wireless communications and more particularly to inductive components of wireless communication devices.

2. Description of Related Art

Communication systems are known to support wireless and wire lined communications between wireless and/or wire lined communication devices. Such communication systems range from national and/or international cellular telephone systems to the Internet to point-to-point in-home wireless networks. Each type of communication system is constructed, and hence operates, in accordance with one or more communication standards. For instance, wireless communication systems may operate in accordance with one or more standards including, but not limited to, IEEE 802.11, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, two-way radio, personal digital assistant (PDA), personal computer (PC), laptop computer, home entertainment equipment, et cetera communicates directly or indirectly with other wireless communication devices. For direct communications (also known as point-to-point communications), the participating wireless communication devices tune their receivers and transmitters to the same channel or channels (e.g., one of the plurality of radio frequency (RF) carriers of the wireless communication system) and communicate over that channel(s). For indirect wireless communications, each wireless communication device communicates directly with an associated base station (e.g., for cellular services) and/or an associated access point (e.g., for an in-home or in-building wireless network) via an assigned channel. To complete a communication connection between the wireless communication devices, the associated base stations and/or associated access points communicate with each other directly, via a system controller, via the public switch telephone network, via the Internet, and/or via some other wide area network.

For each wireless communication device to participate in wireless communications, it includes a built-in radio transceiver (i.e., receiver and transmitter) or is coupled to an associated radio transceiver (e.g., a station for in-home and/or in-building wireless communication networks, RF modem, etc.). As is known, the transmitter includes a data modulation stage, one or more intermediate frequency stages, and a power amplifier. The data modulation stage converts raw data into baseband signals in accordance with a particular wireless communication standard. The one or more intermediate frequency stages mix the baseband signals with one or more local oscillations to produce RF signals. The power amplifier amplifies the RF signals prior to transmission via an antenna.

As is also known, the receiver is coupled to the antenna and includes a low noise amplifier, one or more intermediate frequency stages, a filtering stage, and a data recovery stage. The low noise amplifier receives inbound RF signals via the antenna and amplifies then. The one or more intermediate frequency stages mix the amplified RF signals with one or more local oscillations to convert the amplified RF signal into baseband signals or intermediate frequency (IF) signals. The filtering stage filters the baseband signals or the IF signals to attenuate unwanted out of band signals to produce filtered signals. The data recovery stage recovers raw data from the filtered signals in accordance with the particular wireless communication standard.

Within both the receiver and transmitter, components, such as the mixers of the IF stages, the amplifiers, etc., include inductive components. Typically, producing an on-chip inductor has many limitations, including die area consumption, quality factor, and inductance values. Further, with many receivers and transmitters required to operate in accordance with multiple wireless communication standards (e.g., IEEE 802.11a, b, g, Bluetooth, etc.) having multiple frequency bands (e.g., 2.4 GHz, 5.25 GHz, 5.75 GHz, etc.), the receivers and transmitters include multiple inductive components to meet these various requirements. However, such multiple inductive components consume a significant amount of die area.

Therefore, a need exists for an adjustable differential inductor that enables receivers and transmitters to comply with multiple wireless communication standards.

### BRIEF SUMMARY OF THE INVENTION

The adjustable differential inductor of the present invention substantially meets these needs and others. In one embodiment, an adjustable differential inductor includes a first winding section, a second winding section, a third winding section, a fourth winding section, and a switching network operably coupled to configure the first, second, third, and fourth windings for a first differential inductance in a first mode and to configure two of the first, second, third, and fourth windings for a second differential inductance in a second mode. Such an adjustable differential inductor may be used in a low noise amplifier, a down conversion module, an up conversion module, and/or a power amplifier of a radio frequency integrated circuit.

### BRIEF DESCRIPTION OF THE SEVERAL VIEWS OF THE DRAWINGS

FIG. 1 is a schematic block diagram of a wireless communication system in accordance with the present invention;

FIG. 2 is a schematic block diagram of a wireless communication device in accordance with the present invention;

FIG. 3 is a schematic block diagram of a low noise amplifier in accordance with the present invention;

FIG. 4 is a schematic block diagram of a power amplifier in accordance with the present invention;

FIG. 5 is a schematic block diagram of a mixer of a conversion module in accordance with the present invention;

FIG. 6 is a schematic block diagram of an adjustable differential inductor in accordance with the present invention;

FIG. 7 is a schematic block diagram of another adjustable differential inductor in accordance with the present invention;

FIG. 8 is a schematic block diagram of yet another adjustable differential inductor in accordance with the present invention;

FIG. 9 is a schematic block diagram of a further adjustable differential inductor in accordance with the present invention; and

FIG. 10 is a schematic block diagram of a still further adjustable differential inductor in accordance with the present invention.

### DETAILED DESCRIPTION OF THE INVENTION

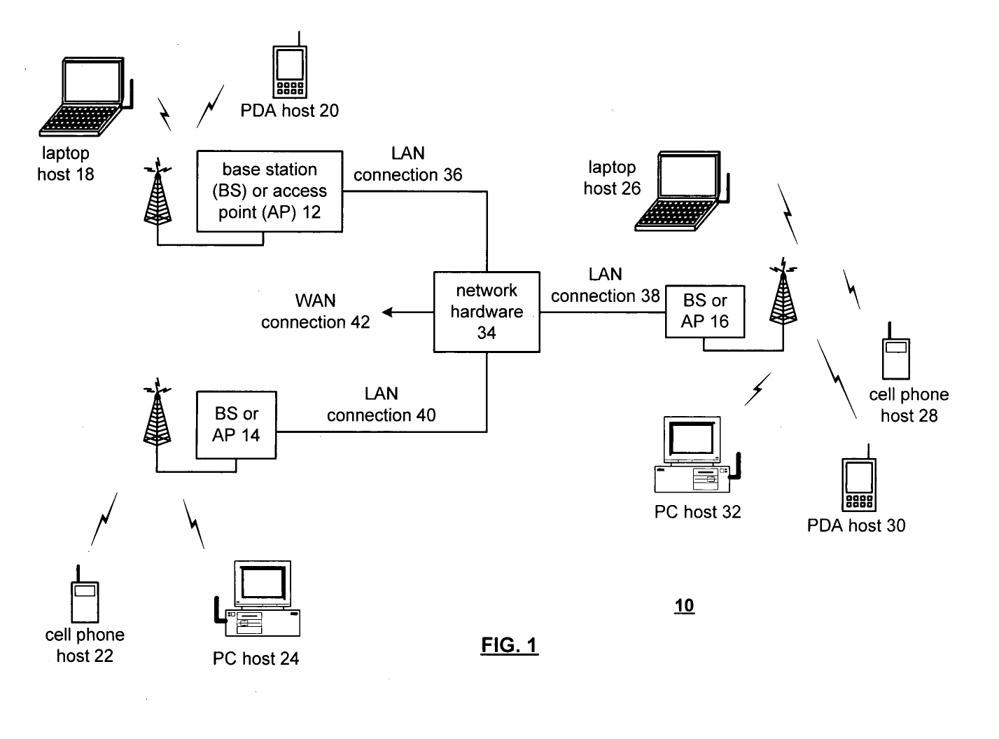

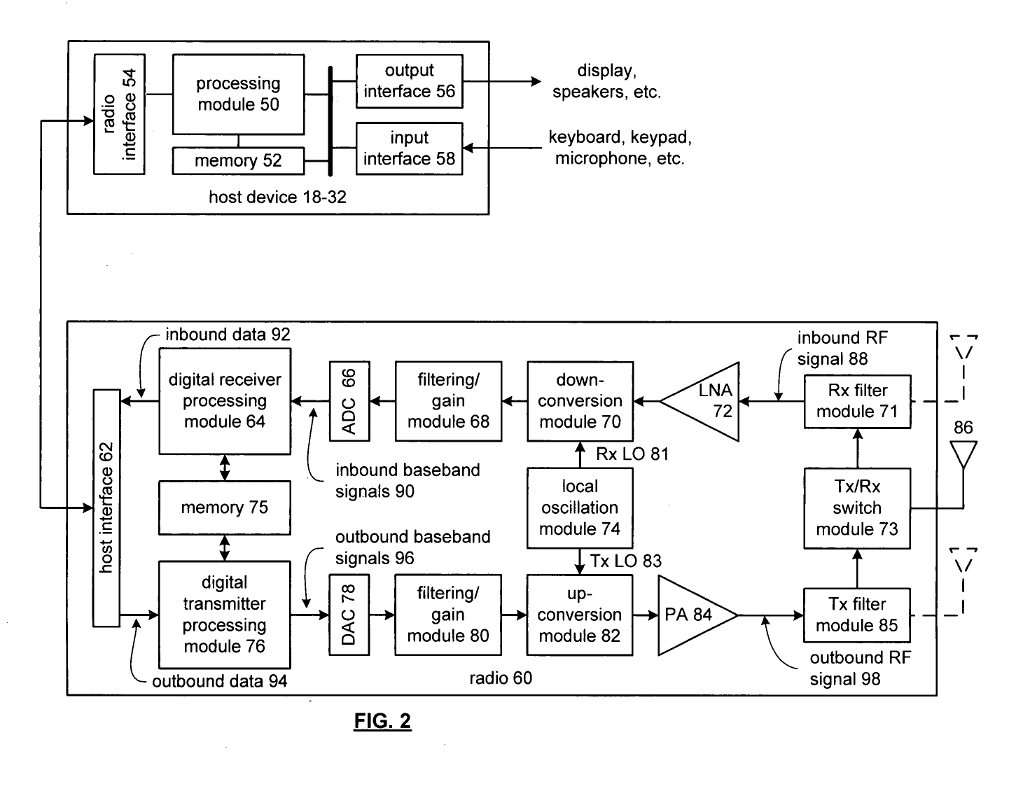

FIG. 1 is a schematic block diagram illustrating a communication system 10 that includes a plurality of base stations and/or access points 12-16, a plurality of wireless communication devices 18-32 and a network hardware component 34. The wireless communication devices 18-32 may be laptop host computers 18 and 26, personal digital assistant hosts 20 and 30, personal computer hosts 24 and 32 and/or cellular telephone hosts 22 and 28. The details of the wireless communication devices will be described in greater detail with reference to FIG. 2.

The base stations or access points 12-16 are operably coupled to the network hardware 34 via local area network connections 36, 38 and 40. The network hardware 34, which may be a router, switch, bridge, modem, system controller, et cetera provides a wide area network connection 42 for the communication system 10. Each of the base stations or access points 12-16 has an associated antenna or antenna array to communicate with the wireless communication devices in its area. Typically, the wireless communication devices register with a particular base station or access point 12-14 to receive services from the communication system 10. For direct connections (i.e., point-to-point communications), wireless communication devices communicate directly via an allocated channel.

Typically, base stations are used for cellular telephone systems and like-type systems, while access points are used for in-home or in-building wireless networks. Regardless of the particular type of communication system, each wireless communication device includes a built-in radio and/or is coupled to a radio.

FIG. 2 is a schematic block diagram illustrating a wireless communication device that includes the host device 18-32 and an associated radio 60. For cellular telephone hosts, the radio 60 is a built-in component. For personal digital assistants hosts, laptop hosts, and/or personal computer hosts, the radio 60 may be built-in or an externally coupled component.

As illustrated, the host device 18-32 includes a processing module 50, memory 52, a radio interface 54, an input interface 58, and an output interface 56. The processing module 50 and memory 52 execute the corresponding instructions that are typically done by the host device. For example, for a cellular telephone host device, the processing module 50 performs the corresponding communication functions in accordance with a particular cellular telephone standard.

The radio interface 54 allows data to be received from and sent to the radio 60. For data received from the radio 60 (e.g., inbound data), the radio interface 54 provides the data to the processing module 50 for further processing and/or routing to the output interface 56. The output interface 56 provides connectivity to an output display device such as a display, monitor, speakers, et cetera such that the received data may be displayed. The radio interface 54 also provides data from the processing module 50 to the radio 60. The processing module 50 may receive the outbound data from an input device such as a keyboard, keypad, microphone, et cetera via the input interface 58 or generate the data itself. For data received via the input interface 58, the processing module 50 may perform a corresponding host function on the data and/or route it to the radio 60 via the radio interface 54.

Radio 60 includes a host interface 62, digital receiver processing module 64, an analog-to-digital converter 66, a filtering/gain module 68, an IF mixing down conversion stage 70, a receiver filter 71, a low noise amplifier 72, a transmitter/receiver switch 73, a local oscillation module 74, memory 75, a digital transmitter processing module 76, a digital-to-analog converter 78, a filtering/gain module 80, an IF mixing up conversion stage 82, a power amplifier 84, a transmitter filter module 85, and an antenna 86. The antenna 86 may be a single antenna that is shared by the transmit and receive paths as regulated by the Tx/Rx switch 73, or may include separate antennas for the transmit path and receive path. The antenna implementation will depend on the particular standard to which the wireless communication device is compliant.

The digital receiver processing module 64 and the digital transmitter processing module 76, in combination with operational instructions stored in memory 75, execute digital receiver functions and digital transmitter functions, respectively. The digital receiver functions include, but are not limited to, digital intermediate frequency to baseband conversion, demodulation, constellation demapping, decoding, and/or descrambling. The digital transmitter functions include, but are not limited to, scrambling, encoding, constellation mapping, modulation, and/or digital baseband to IF conversion. The digital receiver and transmitter processing modules 64 and 76 may be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 75 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 64 and/or 76 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

In operation, the radio 60 receives outbound data 94 from the host device via the host interface 62. The host interface 62 routes the outbound data 94 to the digital transmitter processing module 76, which processes the outbound data 94 in accordance with a particular wireless communication standard (e.g., IEEE 802.11, Bluetooth, et cetera) to produce outbound baseband signals 96. The outbound baseband signals 96 will be digital base-band signals (e.g., have a zero IF) or a digital low IF signals, where the low IF typically will be in the frequency range of one hundred kilohertz to a few megahertz.

The digital-to-analog converter 78 converts the outbound baseband signals 96 from the digital domain to the analog domain. The filtering/gain module 80 filters and/or adjusts the gain of the analog signals prior to providing it to the IF mixing stage 82. The IF mixing stage 82 converts the analog baseband or low IF signals into RF signals based on a transmitter local oscillation 83 provided by local oscillation module 74. The power amplifier 84 amplifies the RF signals to produce outbound RF signals 98, which are filtered by the transmitter filter module 85. The antenna 86 transmits the outbound RF signals 98 to a targeted device such as a base station, an access point and/or another wireless communication device.

The radio 60 also receives inbound RF signals 88 via the antenna 86, which were transmitted by a base station, an access point, or another wireless communication device. The antenna 86 provides the inbound RF signals 88 to the receiver filter module 71 via the Tx/Rx switch 73, where the Rx filter 71 bandpass filters the inbound RF signals 88. The Rx filter 71 provides the filtered RF signals to low noise amplifier 72, which amplifies the signals 88 to produce an amplified inbound RF signals. The low noise amplifier 72 provides the amplified inbound RF signals to the IF mixing module 70, which directly converts the amplified inbound RF signals into an inbound low IF signals or baseband signals based on a receiver local oscillation 81 provided by local oscillation module 74. The down conversion module 70 provides the inbound low IF signals or baseband signals to the filtering/gain module 68. The filtering/gain module 68 filters and/or gains the inbound low IF signals or the inbound baseband signals to produce filtered inbound signals.

The analog-to-digital converter 66 converts the filtered inbound signals from the analog domain to the digital domain to produce inbound baseband signals 90, where the inbound baseband signals 90 will be digital base-band signals or digital low IF signals, where the low IF typically will be in the frequency range of one hundred kilohertz to a few megahertz. The digital receiver processing module 64 decodes, descrambles, demaps, and/or demodulates the inbound baseband signals 90 to recapture inbound data 92 in accordance with the particular wireless communication standard being implemented by radio 60. The host interface 62 provides the recaptured inbound data 92 to the host device 18-32 via the radio interface 54.

As one of average skill in the art will appreciate, the wireless communication device of FIG. 2 may be implemented using one or more integrated circuits. For example, the host device may be implemented on one integrated circuit, the digital receiver processing module 64, the digital transmitter processing module 76 and memory 75 may be implemented on a second integrated circuit, and the remaining components of the radio 60, less the antenna 86, may be implemented on a third integrated circuit. As an alternate example, the radio 60 may be implemented on a single integrated circuit. As yet another example, the processing module 50 of the host device and the digital receiver and transmitter processing modules 64 and 76 may be a common processing device implemented on a single integrated circuit. Further, the memory 52 and memory 75 may be implemented on a single integrated circuit and/or on the same integrated circuit as the common processing modules of processing module 50 and the digital receiver and transmitter processing module 64 and 76.

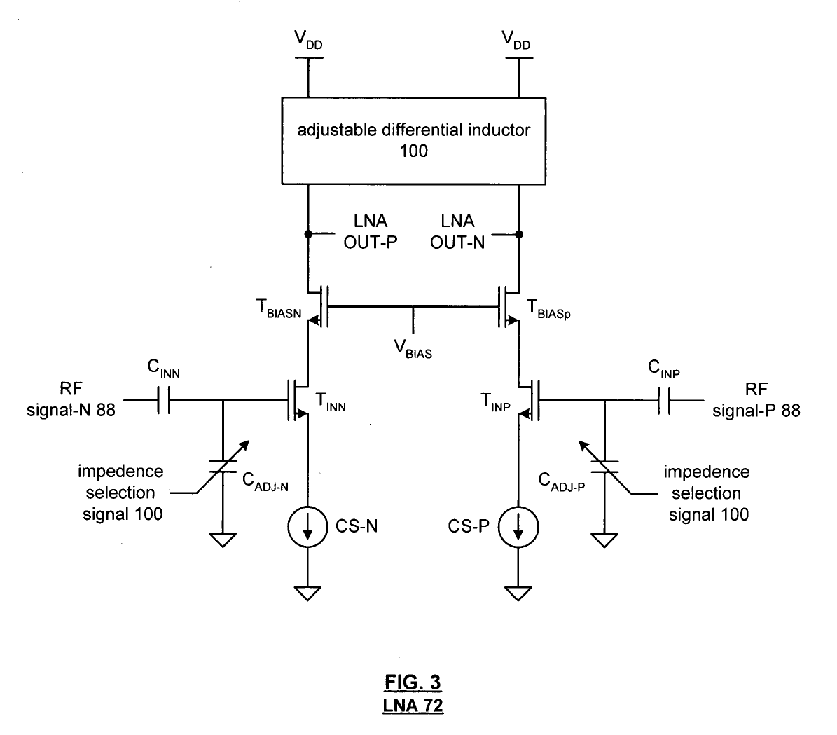

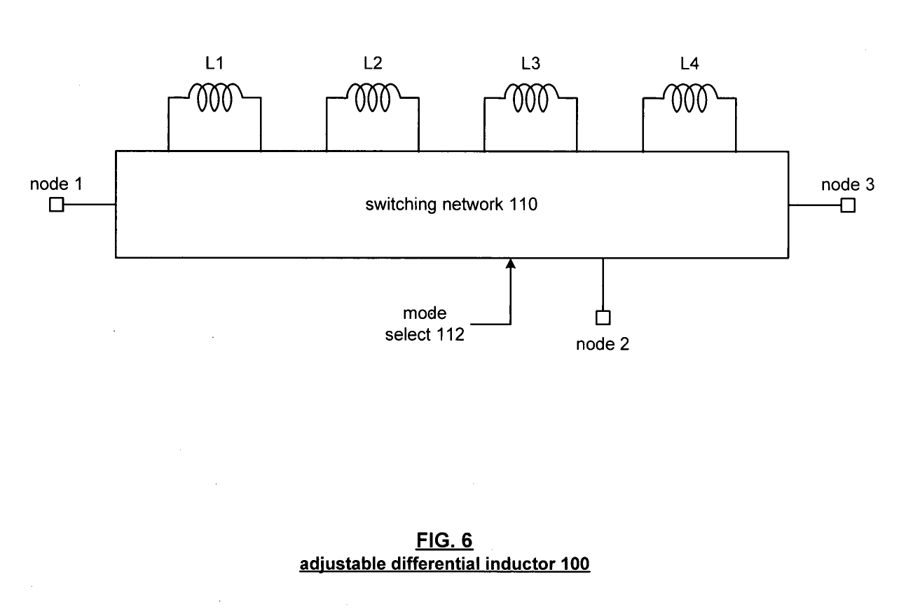

FIG. 3 is a schematic block diagram of a low noise amplifier 72 that includes an adjustable differential inductor 100 (which will be described in greater detail with reference to FIGS. 6-10), two bias transistors T_{BIASN} and T_{BIASP}, to input transistors T_{INN} and T_{INP}, two input capacitors C_{INN} and C_{INP}, two adjustable capacitors C_{ADJN} and C_{ADJP}, and two current sources CS-N and CS-P. The adjustable capacitors C_{ADJN} and C_{ADJP} are adjusted based on the impedance selection signal 100 to ensure that the imaginary component of the input impedance of the low noise amplifier remains substantially constant regardless of whether the low noise amplifier is on or off.

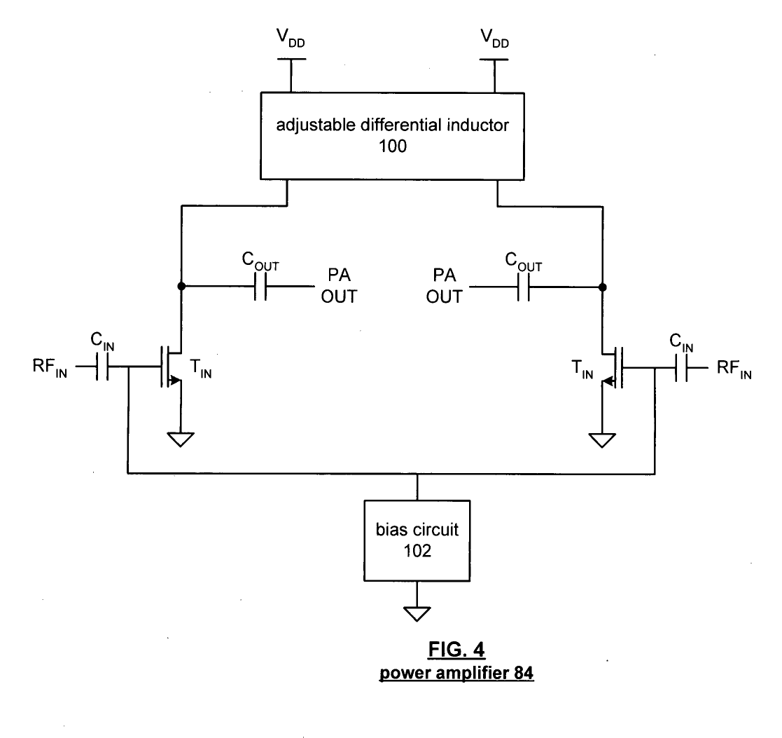

FIG. 4 is a schematic block diagram of at least a portion of a power amplifier 84 that includes an adjustable differential inductor 100 (which will be described in greater detail with reference to FIGS. 6-10), a bias circuit 102, input transistors T_{IN}, input capacitors C_{IN}, and output capacitors C_{OUT}. The input capacitors are operably coupled to provide a differential RF input signal to the input transistors. Based on the biasing level provided by the bias circuit 102 and the load provided by the adjustable differential inductor 100, the transistors amplify the RF input signal to produce an output RF signals that is AC coupled via the output capacitors to the T/R switch or an RF transmit filter.

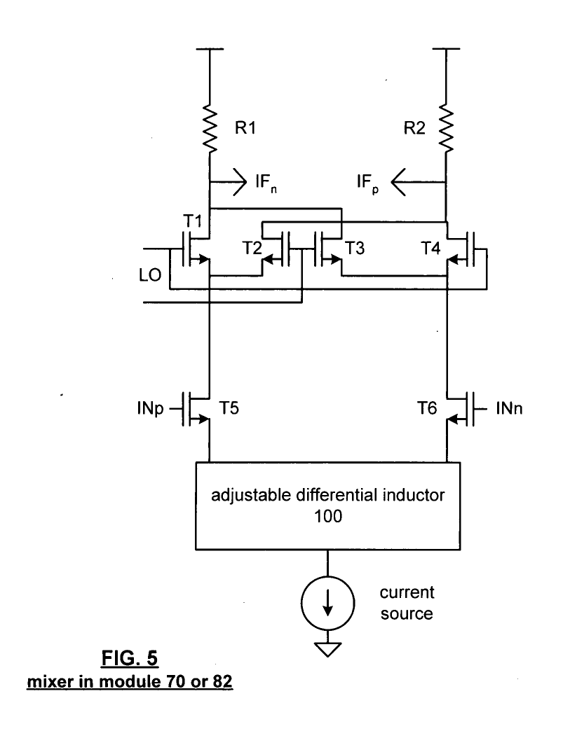

FIG. 5 is a schematic block diagram of a mixer in module 70 or 82 that includes an adjustable differential inductor 100 (which will be described in greater detail with reference to FIGS. 6-10), a current source, switching transistors T1-T6, and load resistors R1, R2. In operation, transistors T5 and T6 receive a differential input signal and transistors T1-T4 receive a differential local oscillation (LO). Based on the current provided by the current source and the loading provided by the resistors and the adjustable differential inductor 100, the mixer mixes the local oscillation with the input signal.

By incorporating the adjustable differential inductor 100 in the circuits of FIGS. 3-5, the circuits may be readily adjusted to operate in different frequency bands. For example, with one configuration of the adjustable differential inductor 100, the circuits of FIGS. 3-5 may operate in the 2.4 GHz frequency band, while, in another configuration, the circuits of FIGS. 3-5 may operate in the 5.25 GHz frequency band.

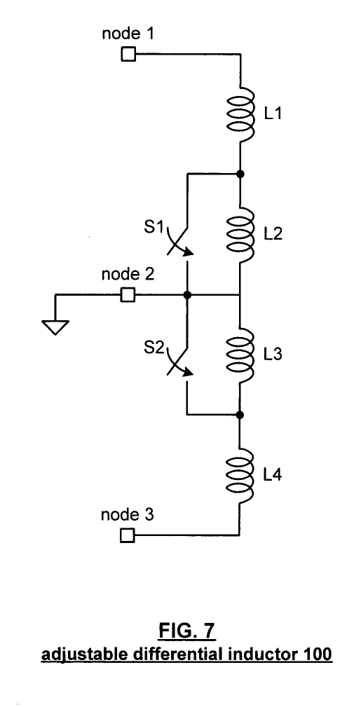

FIG. 6 is a schematic block diagram of an adjustable differential inductor 100 that includes a plurality of windings L1-L4, and a switching network 110. The switching network 110 includes three nodes, which provide the connectivity to the adjustable differential inductor 100. Based on a mode select signal 112, the switching network couples the plurality of windings L1-L4 to the three nodes to provide particular differential inductor configurations. FIGS. 7-10 illustrate just some of the possible configurations of the adjustable differential inductor 100.

FIG. 7 is a schematic block diagram of an embodiment of the adjustable differential inductor 100 that includes two switches S1 and S2 as the switching network 110. In this embodiment, the plurality of windings L1-L4 is serially coupled with nodes 1-3 coupled to the ends and center tap of the windings. As is further shown, switch S1 is in parallel with winding L2 and switch S2 is in parallel with winding L3. In a first mode, switches S1 and S2 are open such that the inductance between nodes 1 and 2 is based on the series inductance of L1 and L2 and the inductance between nodes 2 and 3 is based on the series inductance of L3 and L4. In a second mode, switches S1 and S2 are closed such that the inductance between nodes 1 and 2 is based on the inductance of L1 and the inductance between nodes 2 and 3 is based on the inductance of L4.

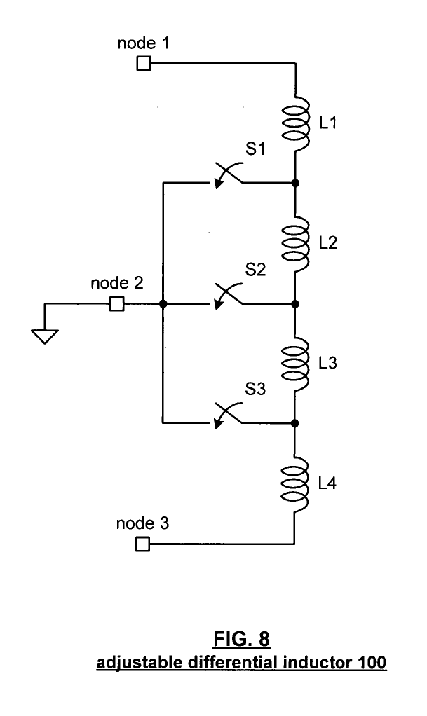

FIG. 8 is a schematic block diagram of another embodiment of the adjustable differential inductor 100 that includes three switches S1, S2 and S3 as the switching network 110. In this embodiment, the plurality of windings L1-L4 is serially coupled with nodes 1 and 3 coupled to the ends of the windings and node 2 coupled to switch S2. As is further shown, switches S1 and S2 are in parallel with winding L2 and switches S2 and S3 are in parallel with winding L3. In a first mode, switches S1 and S3 are open and switch S2 is closed such that the inductance between nodes 1 and 2 is based on the series inductance of L1 and L2 and the inductance between nodes 2 and 3 is based on the series inductance of L3 and L4. In a second mode, switches S1 and S3 are closed and switch S2 is open such that the inductance between nodes 1 and 2 is based on the inductance of L1 and the inductance between nodes 2 and 3 is based on the inductance of L4.

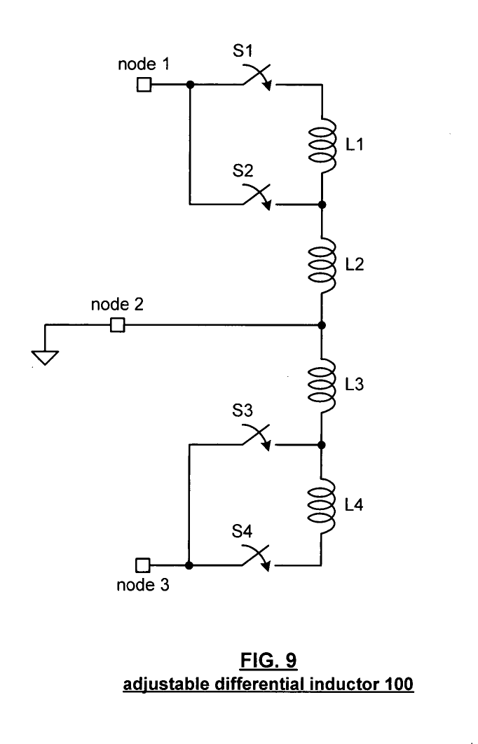

FIG. 9 is a schematic block diagram of another embodiment of the adjustable differential inductor 100 that includes four switches S1, S2, S3 and S4 as the switching network 110. In this embodiment, the plurality of windings L1-L4 is serially coupled with nodes 1 and 3 coupled to the ends of the windings via switches S1 and S4 and node 2 coupled to the center tap of the windings. As is further shown, switches S1 and S2 are in parallel with winding L1 and switches S3 and S4 are in parallel with winding L4. In a first mode, switches S1 and S4 are closed and switches S2 and S3 are open such that the inductance between nodes 1 and 2 is based on the series inductance of L1 and L2 and the inductance between nodes 2 and 3 is based on the series inductance of L3 and L4. In a second mode, switches S1 and S4 are open and switches S2 and S3 are closed such that the inductance between nodes 1 and 2 is based on the inductance of L2 and the inductance between nodes 2 and 3 is based on the inductance of L3.

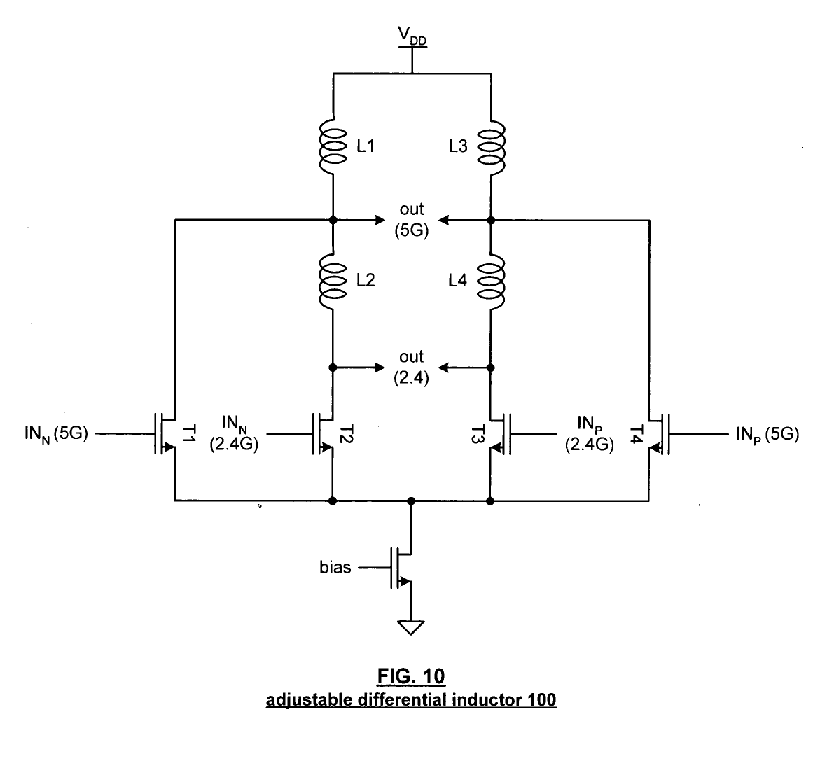

FIG. 10 is a schematic block diagram of another embodiment of the adjustable differential inductor 100 that includes four transistors T1, T2, T3 and T4 as the switching network 110. In this embodiment, transistors T1 and T4 are active for signals having a frequency in the 2.4 GHz band and transistors T2 and T3 are active for signals having a frequency in the 5 GHz band.

As one of ordinary skill in the art will appreciate, the term “substantially” or “approximately”, as may be used herein, provides an industry-accepted tolerance to its corresponding term and/or relativity between items. Such an industry-accepted tolerance ranges from less than one percent to twenty percent and corresponds to, but is not limited to, component values, integrated circuit process variations, temperature variations, rise and fall times, and/or thermal noise. Such relativity between items ranges from a difference of a few percent to magnitude differences. As one of ordinary skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled”. As one of ordinary skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The preceding discussion has presented an adjustable differential inductor and applications thereof. As one of ordinary skill in the art will appreciate, other embodiments may be derived from the teachings of the present invention without deviating from the scope of the claims.

What is claimed is:

1. An adjustable differential inductor comprises:
a first winding section;
a second winding section;
a third winding section;
a fourth winding section; and
a switching network operably coupled to configure the first, second, third, and fourth windings for a first differential inductance in a first mode and to configure two of the first, second, third, and fourth windings for a second differential inductance in a second mode.

2. The adjustable differential inductor of claim 1, wherein the switching network comprises:
a first switch having a first node and a second node, wherein the first node of the first switch is coupled to a common node of the first and second winding sections and the second node of the first switch is coupled a ground reference; and
a second switch having a first node and a second node, wherein the first node of the second switch is coupled to the ground reference and the second node of the second switch is coupled to a common node of the third and fourth winding sections, wherein a common node of the second and third winding sections is coupled to the ground reference.

3. The adjustable differential inductor of claim 1, wherein the switching network comprises:
a first switch having a first node and a second node, wherein the first node of the first switch is coupled to a common node of the first and second winding sections and the second node of the first switch is coupled a ground reference;
a second switch having a first node and a second node, wherein the first node of the second switch is coupled to a common node of the second and third winding sections and the second node of the second switch is coupled to the ground reference; and
a third switch having a first node and a second node, wherein the first node of the third switch is coupled to a common node of the third and fourth winding sections and the second node of the third switch is coupled to the ground reference.

4. The adjustable differential inductor of claim 1, wherein the switching network comprises:
a first switch coupled in series with a first node of the first winding section, wherein a second node of the first winding section is coupled to a first node of the second winding section;
a second switch coupled in series with the first node of the second winding section, wherein a second node of the second winding section is coupled to a first node of the third winding section;
a third switch coupled in series with a second node of the third winding section, wherein the second node of the third winding section is coupled to a first node of the fourth winding section; and
a fourth switch coupled in series with a second node of the fourth winding section, wherein the second node of the third winding section is coupled to a first node of the fourth winding section, wherein the second node of the second winding section is coupled to a ground reference.

5. The adjustable differential inductor of claim 1 comprises:
the first mode corresponding to a carrier frequency of 2.4 GHz; and
the second mode corresponding to a carrier frequency of 5 GHz.

6. A radio frequency integrated circuit (RFIC) comprises:
a low noise amplifier operably coupled to amplify inbound radio frequency (RF) signals to produce amplified RF signals;
a down conversion module operably coupled to convert the amplified inbound RF signals into low intermediate frequency (IF) inbound signals based on a receiver local oscillation;
analog to digital conversion module operably coupled to convert the low IF inbound signals into inbound low IF digital signals;
processing module operably coupled to convert the inbound low IF digital signals into inbound data and to convert outbound data into outbound low IF digital signals;
digital to analog conversion module operably coupled to convert the outbound low IF digital signals into outbound low IF signals;
up conversion module operably coupled to convert the outbound low IF signals into outbound RF signals based on a transmitter local oscillation;
power amplifier operably coupled to amplify the outbound RF signals; and
a local oscillation module operably coupled to produce the receiver local oscillation and the transmitter local oscillation, wherein at least one of the low noise amplifier, the down conversion module, the up conversion module, and the power amplifier include an adjustable differential inductor that includes:
a first winding section;
a second winding section;
a third winding section;
a fourth winding section; and
a switching network operably coupled to configure the first, second, third, and fourth windings for a first differential inductance in a first mode and to configure two of the first, second, third, and fourth windings for a second differential inductance in a second mode.

7. The RFIC of claim 6, wherein the switching network comprises:
a first switch having a first node and a second node, wherein the first node of the first switch is coupled to a common node of the first and second winding sections and the second node of the first switch is coupled a ground reference; and
a second switch having a first node and a second node, wherein the first node of the second switch is coupled to the ground reference and the second node of the second switch is coupled to a common node of the third and fourth winding sections, wherein a common node of the second and third winding sections is coupled to the ground reference.

8. The RFIC of claim 6, wherein the switching network comprises:
a first switch having a first node and a second node, wherein the first node of the first switch is coupled to a common node of the first and second winding sections and the second node of the first switch is coupled a ground reference;
a second switch having a first node and a second node, wherein the first node of the second switch is coupled to a common node of the second and third winding sections and the second node of the second switch is coupled to the ground reference; and
a third switch having a first node and a second node, wherein the first node of the third switch is coupled to a common node of the third and fourth winding sections and the second node of the third switch is coupled to the ground reference.

9. The RFIC of claim 6, wherein the switching network comprises:
a first switch coupled in series with a first node of the first winding section, wherein a second node of the first winding section is coupled to a first node of the second winding section;
a second switch coupled in series with the first node of the second winding section, wherein a second node of the second winding section is coupled to a first node of the third winding section;
a third switch coupled in series with a second node of the third winding section, wherein the second node of the third winding section is coupled to a first node of the fourth winding section; and
a fourth switch coupled in series with a second node of the fourth winding section, wherein the second node of the third winding section is coupled to a first node of the fourth winding section, wherein the second node of the second winding section is coupled to a ground reference.

10. The RFIC of claim 6, wherein the adjustable differential inductor comprises:
the first mode corresponding to a carrier frequency of 2.4 GHz; and
the second mode corresponding to a carrier frequency of 5 GHz.
